(19) United States
(12) Patent Application Publication
(10) Pub. No.: US 2012/0274647 A1
(43) Pub. Date: Nov. 1, 2012

(54) PIEZOELECTRIC RESONATORS AND FABRICATION PROCESSES

(75) Inventors: Je-Hsiung Lan, San Diego, CA (US); Sang-June Park, San Diego, CA (US); Jonghae Kim, San Diego, CA (US); Evgeni Gousev, Saratoga, CA (US); Matthew Nowak, San Diego, CA (US); Philip J. Stephanou, Mountain View, CA (US); Justin Black, Santa Clara, CA (US); Kurt Petersen, Milpitas, CA (US); Srinivasan Ganapathi, Palo Alto, CA (US)

(73) Assignee: QUALCOMM MEMS TECHNOLOGIES, INC., San Diego, CA (US)

(21) Appl. No.: 13/094,687

(22) Filed: Apr. 26, 2011

(51) Int. Cl. H01L 41/053; G09G 5/39; H01L 41/22; G06T 1/60

(52) U.S. Cl. 345/531; 310/348; 310/340; 345/530; 29/25.35

(57) ABSTRACT

This disclosure provides implementations of electromechanical systems resonator structures, devices, apparatus, systems, and related processes. In one aspect, a sacrificial layer is deposited on an insulating substrate. A lower electrode layer is formed proximate the sacrificial layer. A piezoelectric layer is deposited on the lower electrode layer. An upper electrode layer is formed on the piezoelectric layer. At least a portion of the sacrificial layer is removed to define a cavity such that at least a portion of the lower electrode layer is spaced apart from the insulating substrate.

### TECHNICAL FIELD

This disclosure relates generally to resonators and more specifically to electromechanical systems piezoelectric resonators and fabrication processes.

### DESCRIPTION OF THE RELATED TECHNOLOGY

Electromechanical systems include devices having electrical and mechanical elements, transducers such as actuators and sensors, optical components (e.g., mirrors), and electronics. Electromechanical systems can be manufactured at a variety of scales including, but not limited to, microscales and nanoscales. For example, microelectromechanical systems (MEMS) devices can include structures having sizes ranging from about one micron to hundreds of microns or more. Nanoelectromechanical systems (NEMS) devices can include structures having sizes smaller than one micron including, for example, sizes smaller than several hundred nanometers. Electromechanical elements may be created using deposition, etching, lithography, and/or other micromachining processes that etch away parts of substrates and/or deposited material layers, or that add layers to form electrical, mechanical, and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a metallic membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Various electronic components and circuits can be implemented at the electromechanical systems level. However, conventional techniques for fabricating electromechanical systems devices often have limitations. For example, conventional thickness MEMS filters, such as thickness-extensional mode resonators, are limited to single-frequency operation on a single wafer. Conventional quartz crystal resonators and Surface Acoustic Wave (SAW) filters are often bulky and located off-chip.

MEMS devices, including resonators that are fabricated using conventional silicon-based techniques, can either be fabricated directly above complementary metal oxide semiconductor (CMOS) or other technology integrated circuits (IC) or on separate silicon substrates. Resonators or other MEMS devices that are fabricated on separate substrates may increase the overall system size. Such conventional silicon-based fabrication techniques can also contribute to high systems costs.

### SUMMARY

The structures, devices, apparatus, systems, and processes of the disclosure each have several innovative aspects, no single one of which is solely responsible for the desirable attributes disclosed herein.

Disclosed are implementations of electromechanical systems resonator structures, such as contour mode resonators (CMR), devices, apparatus, systems, and related fabrication processes.

According to one innovative aspect of the subject matter described in this disclosure, a process for forming a resonator structure is performed. A sacrificial layer is deposited on an insulating substrate. A lower electrode layer is formed proximate the sacrificial layer. A piezoelectric layer is deposited on the lower electrode layer. An upper electrode layer is formed on the piezoelectric layer. At least a portion of the sacrificial layer is removed to define a cavity such that at least a portion of the lower electrode layer is spaced apart from the insulating substrate.

In one example, before forming the lower electrode layer, a post oxide layer is deposited to at least partially overlay the sacrificial layer. The lower electrode layer can at least partially overlay the post oxide layer. The post oxide layer can be patterned to define post oxide anchors and expose a portion of the sacrificial layer.

In another example, a portion of the insulating substrate is removed to define a sacrificial release region, and at least a portion of the deposited sacrificial layer is situated in the sacrificial release region.

According to another innovative aspect of the subject matter described in this disclosure, a process for forming a resonator structure is performed. Portions of an insulating substrate are removed to define trenches in the substrate. A material is deposited in the trenches to define border regions. A lower electrode layer is formed proximate the sacrificial layer. A piezoelectric layer is deposited on the lower electrode layer. An upper electrode layer is formed on the piezoelectric layer. At least a portion of the insulating substrate between the border regions is removed to define a cavity such that at least a portion of the lower electrode layer is spaced apart from the insulating substrate.

According to another innovative aspect of the subject matter described in this disclosure, a resonator device includes an insulating substrate. A lower electrode layer has at least a portion spaced apart from the substrate by a cavity defined by release of at least a portion of a sacrificial layer deposited on the insulating substrate. A piezoelectric layer is disposed on the lower electrode layer opposite the insulating substrate. An upper electrode layer is disposed on the piezoelectric layer opposite the lower electrode layer.

In one example, the insulating substrate includes glass or a ceramic material. The sacrificial layer can include a material such as molybdenum (Mo), germanium (Ge), amorphous silicon (a-Si), or poly-crystalline silicon. In another example, the sacrificial layer includes a material such as silicon oxynitride (SiON) or silicon oxide (SiOx).

In one example, a compensation layer is disposed between the lower electrode layer and the cavity. In another example, a post oxide layer has a portion disposed between a portion of the lower electrode layer and the substrate. In another example, a sacrificial layer portion is disposed between a portion of the lower electrode layer and the substrate. In another example, an encapsulation layer overlays at least a portion of the upper electrode layer.

According to another innovative aspect of the subject matter described in this disclosure, a resonator device includes an insulating substrate. A lower electrode layer overlays the insulating substrate. The lower electrode layer has a portion spaced apart from the substrate by a cavity defined by removal of a sacrificial layer. A piezoelectric layer overlays the lower electrode layer opposite the substrate. An upper electrode layer overlays the piezoelectric layer opposite the lower electrode layer.

According to another innovative aspect of the subject matter described in this disclosure, a resonator device includes an insulating substrate. A sacrificial layer overlays the substrate. A lower electrode layer overlays the sacrificial layer opposite the substrate. The lower electrode layer has a region spaced apart from the substrate by a cavity defined in the sacrificial layer by release of a portion of the sacrificial layer. A piezoelectric layer overlays the lower electrode layer opposite the sacrificial layer. An upper electrode layer overlays the piezoelectric layer opposite the lower electrode layer.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

The included drawings are for illustrative purposes and serve to provide examples of possible structures and configurations of the disclosed resonator structures, devices, apparatus, systems, and related processes.

FIG. 1 shows an example of a flow diagram illustrating a process for forming a resonator structure, performed in accordance with one implementation.

FIG. 2 shows an example of a flow diagram illustrating a process for forming a staggered resonator structure, performed in accordance with one implementation.

FIGS. 3A-3G show examples of cross-sectional schematic illustrations of stages of staggered resonator fabrication in accordance with a process, for instance, as represented in FIG. 1 or FIG. 2.

FIGS. 4A-4G show examples of perspective views of stages of staggered resonator fabrication in accordance with a process, for instance, as represented in FIG. 1 or FIG. 2.

FIG. 5 shows an example of a top view of a staggered resonator device in accordance with one implementation.

FIG. 6 shows an example of a cross-sectional schematic illustration of a temperature-compensated resonator structure in accordance with one implementation.

FIG. 7 shows an example of a cross-sectional schematic illustration of an airgap resonator structure in accordance with one implementation.

FIG. 8 shows an example of a flow diagram illustrating a process for forming a co-planar resonator structure, performed in accordance with one implementation.

FIGS. 9A-9G show examples of cross-sectional schematic illustrations of stages of co-planar resonator fabrication in accordance with a process, for instance, as represented in FIG. 8.

FIGS. 10A-10F show examples of perspective views of stages of co-planar resonator fabrication in accordance with a process, for instance, as represented in FIG. 8.

FIG. 11 shows an example of a cross-sectional schematic illustration of an encapsulated co-planar resonator structure in accordance with one implementation.

FIG. 12 shows an example of a flow diagram illustrating a process for forming a resonator structure using refilled etch stop trenches, performed in accordance with one implementation.

FIGS. 13A-13H show examples of cross-sectional schematic illustrations of stages of resonator fabrication in accordance with a process, for instance, as represented in FIG. 12.

FIG. 14 shows an example of a flow diagram illustrating a process for forming a resonator structure using a refilled sacrificial release cavity, performed in accordance with one implementation.

FIGS. 15A-15H show examples of cross-sectional schematic illustrations of stages of resonator fabrication in accordance with a process, for instance, as represented in FIG. 14.

FIG. 16 shows an example of a system block diagram illustrating an electronic device incorporating an interferometric modulator display.

FIGS. 17A and 17B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to one having ordinary skill in the art.

The disclosed implementations include examples of structures and configurations of electromechanical systems resonator devices, such as contour mode resonators (CMR). Related apparatus, systems, and fabrication processes and techniques are also disclosed. CMRs are referred to as “contour mode” because of their substantially in-plane mode of vibration, as described in greater detail below. In the case of piezoelectric resonators, an electric field applied between electrodes is transduced into a mechanical strain in a piezoelectric material. Thus, a time-varying electrical signal can be provided to an input electrode of the CMR and transduced to a corresponding time-varying mechanical motion. A portion of this mechanical energy can be converted back to electrical energy at the input electrode or at a separate output electrode. The input and output electrodes are generally disposed in contact with or in proximity to the piezoelectric material. For instance, the electrodes can be located on the same surface or on opposite surfaces of a layer of the piezoelectric material. The frequency of the input electrical signal that produces the greatest substantial amplification of the mechanical displacement amplitude in the piezoelectric material is generally referred to as a resonant frequency of the CMR.

Several resonator structures are disclosed and can be formed on a rigid, insulating substrate, such as glass. The various structures can all be fabricated on a low-cost, high-performance, and large-area glass substrate or panel and include, by way of example: a staggered structure, an airgap structure, a temperature-compensated structure, a co-planar structure, and structures in which portions of the insulating substrate are removed, e.g., by etching. In one or more implementations, the resonator structure is suspended in a cavity and generally includes two conductive electrode layers, with a piezoelectric material disposed between the two layers. The resonator structure is acoustically isolated from the substrate by virtue of the cavity. The resonator structure can be suspended above the cavity by specially designed tethers that are often fabricated in the same layer stack of the resonator structure itself. The tethers serve as physical anchors to hold the resonator structure in the cavity.

In some implementations, the structures are fabricated by depositing a sacrificial (SAC) layer on the substrate; forming a lower electrode layer on the SAC layer; depositing a piezoelectric layer on the lower electrode layer; forming an upper electrode layer on the piezoelectric layer; and removing at least part of the SAC layer to define a cavity. The resulting resonator cavity separates at least a portion of the lower electrode layer from the substrate and provides spaces along the sides of the resonator structure, as illustrated in the accompanying figures, to allow the resonator to vibrate and move in one or more directions with substantial elastic isolation from the remaining substrate. In other implementations, a portion of the substrate itself serves as a SAC material. In these implementations, designated regions of the insulating substrate below the resonator structure can be removed, for example, by etching to define the cavity.

Particular implementations of the subject matter described in this disclosure can be implemented to realize one or more of the following potential advantages. In one or more examples, the fabrication of the disclosed resonator structures is based on surface micro-machining techniques where a thin-film based SAC layer is formed underneath the resonator structure through deposition, photolithography and thin-film etching before being released, as further described below. For example, the SAC layer (such as PVD molybdenum and PECVD amorphous silicon) can be removed by exposure to XeF₂ gas or SF₆ plasma. Surface micro-machining techniques can be used to manufacture the resonators on a low-cost, large-area, flat-panel, rigid, insulating substrate, which can also be used to produce high-performance LCD, OLED, and bi-stable displays. In addition to the cost benefit, the disclosed devices fabricated on an insulating substrate such as glass can have improved RF performance in terms of lower insertion loss and reduced parasitic capacitance. These benefits are derived from the low loss tangent of dielectric substrates such as glass. The resonator fabrication processes described herein are compatible with CMOS integrated circuit (IC) fabrication processes and can be fabricated after a CMOS circuit fabrication process, i.e., as a post-CMOS process.

The disclosed resonator structures can be fabricated on a low-cost, high-performance, large-area insulating substrate or panel. In some implementations, the insulating substrate on which the disclosed resonator structures are formed can be made of display grade glass (alkaline earth boro-aluminosilicate) or soda lime glass. Other suitable insulating materials include silicate glasses, such as alkaline earth aluminosilicate, borosilicate, modified borosilicate, and others. Also, ceramic materials, such as AlOx, Y₂O₃, BN, SiC, AlNx, and GaNx can be used as the insulating substrate material. In other implementations, the insulating substrate is formed of a high-resistivity silicon substrate. SOI substrates, GaAs substrates, InP substrates, and plastic (PEN or PET) substrates, e.g., associated with flexible electronics, can also be used. The substrate can be in conventional IC wafer form, e.g., 4-inch, 6-inch, 8-inch, 12-inch, or in large-area panel form. For example, flat panel display substrates that have dimensions such as 370 mm×470 mm, 920 mm×730 mm, and 2850 mm×3050 mm, can be used.

Some implementations described herein are based on a contour mode (d31) resonator configuration. In such implementations, the resonant frequency of a CMR can be substantially controlled by engineering the lateral dimensions of the piezoelectric material and electrodes. One benefit of such a construction is that multi-frequency RF filters, clock oscillators, transducers or other devices, each including one or more CMRs depending on the desired implementation, can be fabricated on the same substrate. For example, this may be advantageous in terms of cost and size by enabling compact, multi-band filter solutions for RF front-end applications on a single chip. By co-fabricating multiple CMRs, each with different finger widths, as described in greater detail below, multiple frequencies can be addressed on the same die. Arrays of CMRs with different frequencies spanning a range from MHz to GHz can be fabricated on the same substrate.

With the disclosed CMRs, direct frequency synthesis for spread spectrum communication systems may be enabled by multi-frequency narrowband filter banks including high quality (Q) resonators, without the need for phase locked loops. The disclosed CMR implementations can provide for piezoelectric transduction with low motional resistance while maintaining high Q factors and appropriate reactance values that facilitate their interface with contemporary circuitry. Some examples of the disclosed laterally vibrating resonator microstructures provide the advantages of compact size, e.g., on the order of 100 um (micrometers) in length and/or width, low power consumption, and compatibility with high-yield mass-producible components.

While the present application is described with reference to a few specific implementations, the description and specific implementations are merely illustrative and are not to be construed as limiting. Various modifications can be made to the described implementations without departing from the true spirit and scope as defined by the appended claims. For example, the blocks of processes shown and described herein are not necessarily performed in the order indicated. It should also be understood that the processes may include more or fewer blocks than are indicated. In some implementations, blocks described herein as separate blocks may be combined, such as sequential depositing and patterning blocks to form a particular layer. Conversely, what may be described herein as a single block may be implemented in multiple blocks.

Similarly, device functionality may be apportioned by grouping or dividing tasks in any convenient fashion. For example, when blocks are described herein as being performed by a single device (e.g., by a single logic device), the blocks may alternatively be performed by multiple devices and vice versa. Moreover, the specific components, parameters, and numerical values described herein are provided merely by way of example and are in no way limiting. The drawings referenced herein are not necessarily drawn to scale.

In this detailed description, the same reference numbers and designations in different Figures indicate the same elements. By the same token, while different Figures may include illustrations of elements having the same or similar appearance, different reference numbers used in relation to such elements are intended to suggest different elements, for instance, in the form of alternatives to be used in examples of the disclosed implementations.

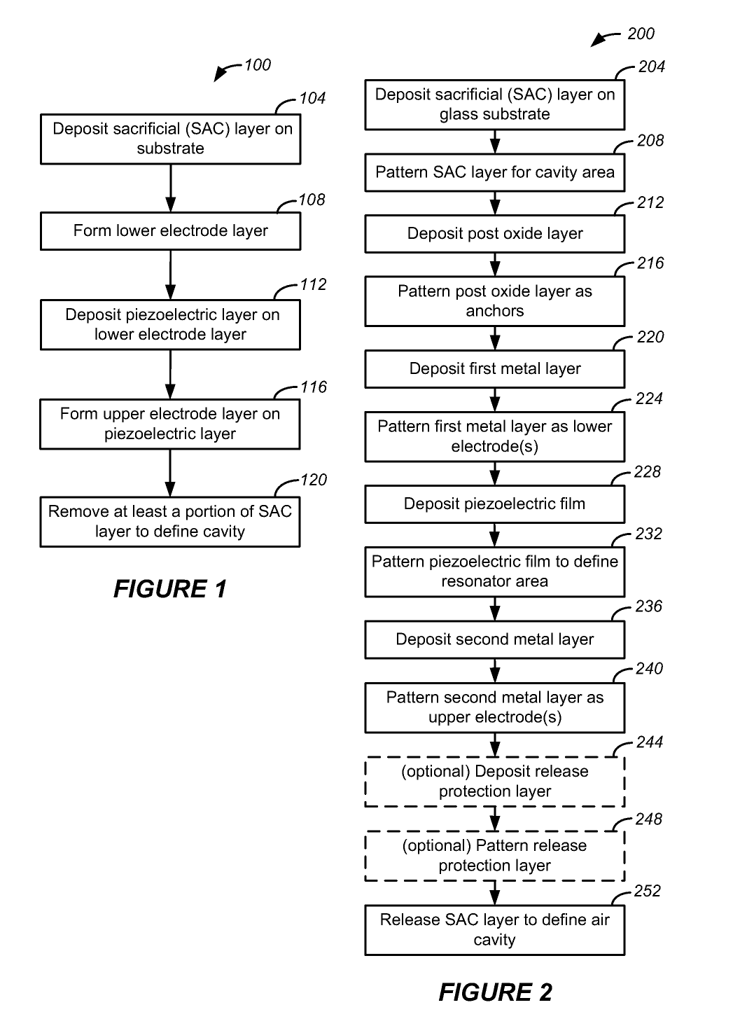

FIG. 1 shows an example of a flow diagram illustrating a process for forming a resonator structure, performed in accordance with one implementation. In FIG. 1, process 100 begins in block 104 in which a sacrificial (SAC) layer is deposited on a substrate. The SAC layer can have various shapes and sizes, and can be shaped to cover all or some portion of the substrate, depending on the desired implementation. In block 108, a lower electrode layer is formed on the SAC layer. The lower electrode layer is made of a conductive material such as metal and can be patterned to define one or more electrodes, depending on the desired configuration. When more than one electrode is defined, the electrodes can be connected at separate ports of the resonator device. In block 112, a piezoelectric layer is deposited on the lower electrode layer. In block 116, an upper electrode layer is then formed on the piezoelectric layer. The upper electrode layer can also be patterned to define more than one electrode. In some implementations, overlaying groups of electrodes can be defined in the upper and lower electrode layers on opposite surfaces of the piezoelectric layer. In block 120, part or all of the SAC layer is removed to define a cavity beneath the resonator structure.

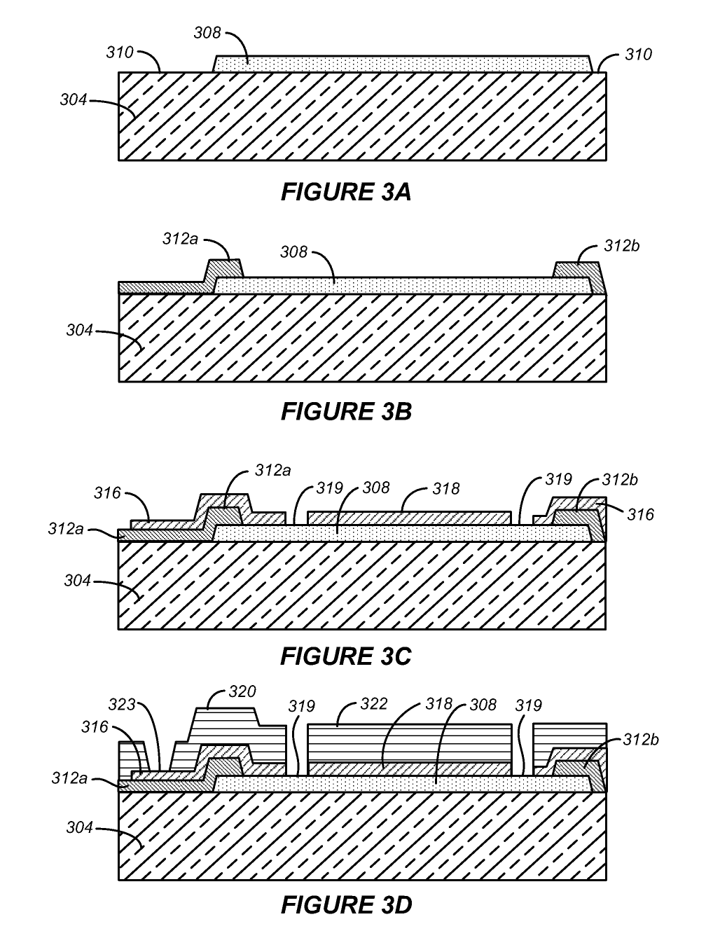

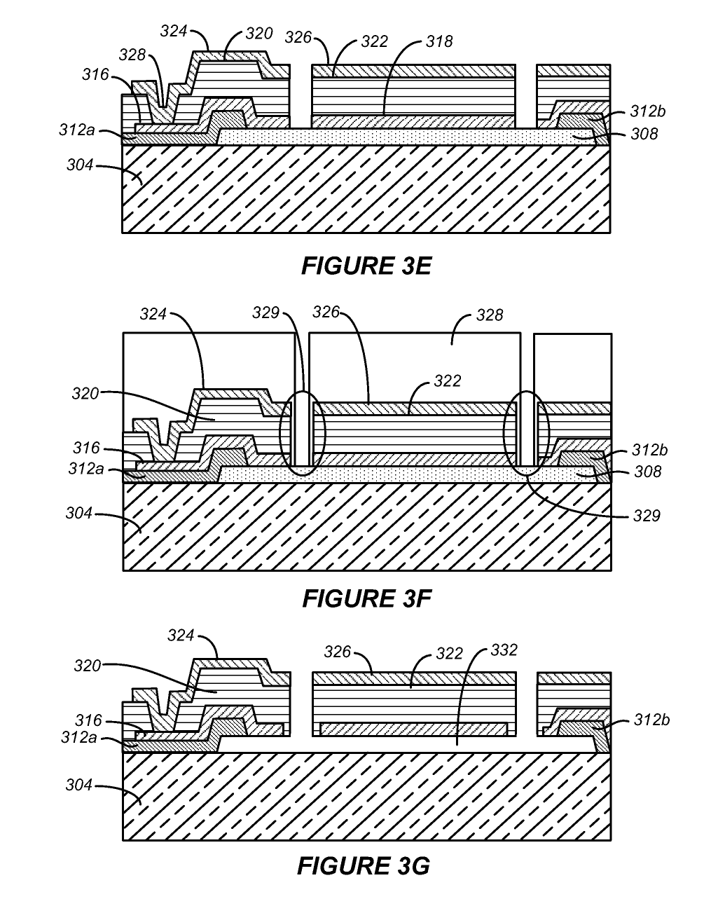

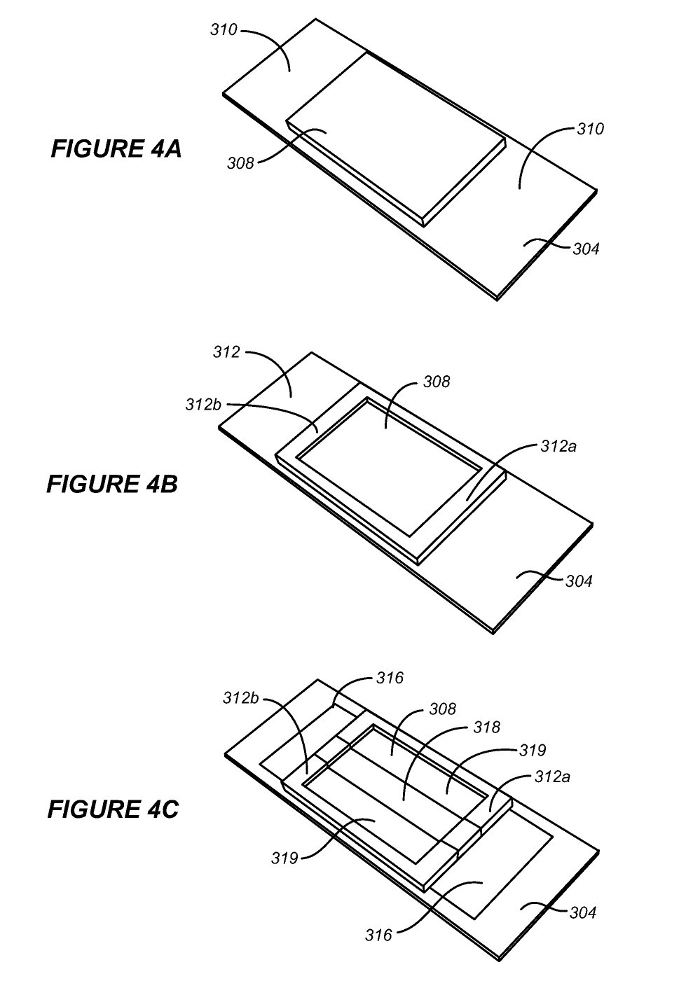

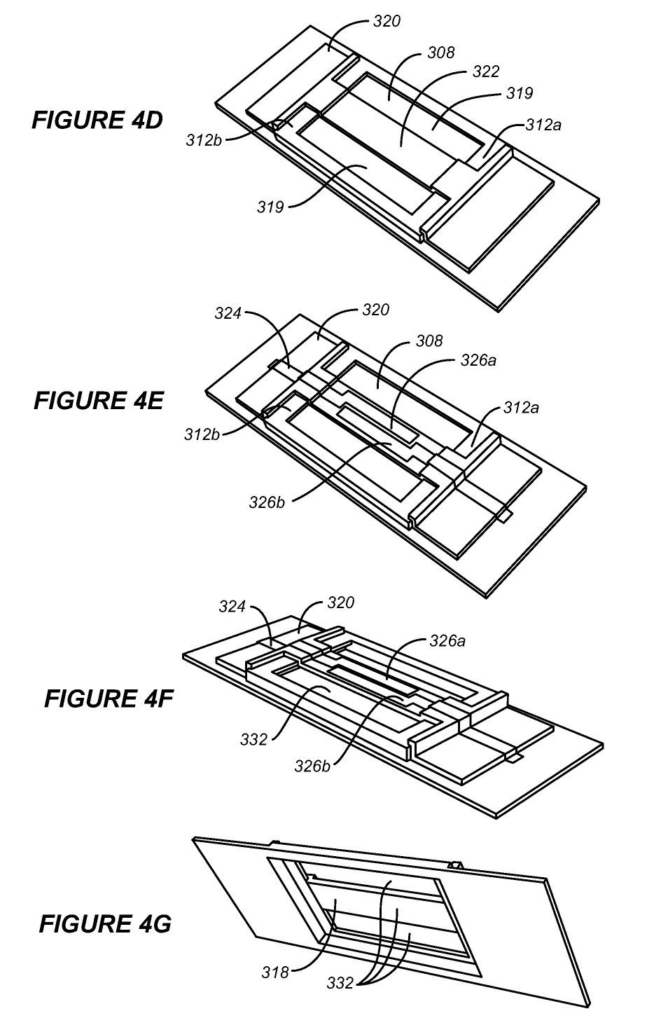

FIG. 2 shows an example of a flow diagram illustrating a process for forming a staggered resonator structure, performed in accordance with one implementation. FIGS. 3A-3G show examples of cross-sectional schematic illustrations of stages of staggered resonator fabrication in accordance with a process, for instance, as represented in FIG. 1 or FIG. 2. FIGS. 4A-4G show examples of perspective views of stages of staggered resonator fabrication in accordance with a process, for instance, as represented in FIG. 1 or FIG. 2.

In FIG. 2, the process 200 begins in block 204 in which a SAC layer 308 is deposited on a glass substrate 304, as shown in FIGS. 3A and 4A. To form the staggered structure of FIGS. 3 and 4, in block 208, SAC layer 308 is patterned using an appropriately shaped and aligned mask such that SAC layer 308 overlays a portion of substrate 304 and exposes end portions 310 of the surface of substrate 304 on respective ends of SAC layer 308. The SAC layer 308 defines a region in which a cavity will be formed to substantially isolate the resonator structure from the substrate, as further described below. The SAC layer 308 can be formed of silicon oxynitride (SiON), silicon oxide (SiOx), molybdenum (Mo), germanium (Ge), amorphous silicon (a-Si), poly-crystalline silicon, and/or various polymers, for example. In some implementations of process 200, the use of Mo, a-Si, or Ge is advantageous, and a suitable thickness of SAC layer 308 is in the range of about 0.5 micrometers (um) to 3 um. In one example, SAC layer 308 is formed of Mo and has a thickness of about 0.5 um.

In block 212, a post oxide layer 312 is deposited over SAC layer 308 and exposed surface portions 310 of glass substrate 304. In block 216, to form the staggered structure of FIGS. 3 and 4, the post oxide layer 312 is patterned using an appropriate mask to expose a top portion of the sacrificial layer 308, as shown in FIGS. 3B and 4B. The remaining portions 312a and 312b of the post oxide layer define anchor structures on sides of the structure, as shown in FIGS. 3B and 4B, covering surface portions 310 of substrate 304. The post oxide layer 312 can be formed of materials such as SiOx and SiON and have a thickness, for example, on the order of about 1 um to 3 um. In other implementations, post oxide layer 312 can be formed of NiSi or MoSi₂. In some examples, post oxide layer 312 is about 0.5 um, or can be thicker, in the range of about 3 um to 5 um.

In block 220, a first metal layer 316 is deposited such that it overlays the post oxide anchors 312a and 312b as well as the exposed region of SAC layer 308. Metal layer 316 can be formed of Al, Al/TiN/Al, AlCu, Mo, or other appropriate materials, and have a thickness of 750 to 3000 Angstroms depending on the desired implementation. In some cases, metal layer 316 is deposited as a bi-layer with a metal such as Mo deposited on top of a seed layer such as AlN. An appropriate thickness for the seed layer can be, for example, 100 to 1000 Angstroms. When Mo is used, the thickness can be about 3000 Angstroms. Other suitable materials for metal layer 316 include AlSi, AlCu, Ti, TiN, Al, Pt, Ni, W, Ru, and combinations thereof. Thicknesses can range from about 0.1 um to 0.3 um, depending on the desired implementation. As shown in FIGS. 3C and 4C, in block 224, the first metal layer 316 is patterned using, for instance, an appropriate mask to define one or more lower electrodes 318. In some implementations, the one or more lower electrodes can be shaped to match overlaying upper electrodes. In the example of FIGS. 3C and 4C, metal layer 316 is formed to have a single electrode 318 in the shape of a strip, which extends laterally across SAC layer 308 and exposes SAC layer 308 on sides 319 of the strip, as shown in FIG. 4C. The exposed areas 319 of SAC layer 308 in FIG. 4C are shown as vias in the cross section depicted by FIGS. 3C-3G, for purposes of illustration.

In block 228, a piezoelectric layer, e.g., film 320, is deposited on the structure. In block 232, the piezoelectric film 320 is patterned using an appropriate mask such that strip 322 of piezoelectric film 320 directly overlays lower electrode portion 318, shown in FIGS. 3D and 4D. Again, as with the deposition and formation of lower electrode layer 318, side areas 319 of SAC layer 308 remain exposed from above. The piezoelectric layer can be formed of AlN and have a thickness, for example, between about 1 um and 2 um. In one example, an AlN piezoelectric film has a thickness of about 1.2 um. Piezoelectric film 320 is patterned at one end of the structure to have one or more vias 323, exposing a portion of first metal layer 316 for conductive contact to be made to first metal layer 316, as shown in FIG. 3D.

In FIG. 2, a second metal layer 324 is deposited and patterned, in blocks 236 and 240, to define upper electrodes 326, as shown in FIGS. 3E and 4E. The second metal layer 324 can be formed of AlCu, for example, as well as other materials as described above for forming first metal layer 316. In one example, second metal layer 324 is formed of AlCu, and has a thickness of about 2000 Angstroms. Other suitable thicknesses range from about 0.1 um to 0.3 um. As illustrated in FIG. 4E, when second metal layer 324 is patterned, in some implementations, a pair of adjacent electrodes 326a and 326b is formed. In one implementation, electrodes 326a and 326b have longitudinal axes extending along the structure from opposite ends, as shown in FIG. 4E. Thus, the respective electrodes 326a and 326b can be connected to different ports, depending on the desired configuration of input and output signals using the resonator structure. In some implementations, a contact region 328 of second metal layer 324 can be deposited in via 323 so the first and second metal layers are in conductive contact with one another.

Following the formation of the second metal layer 324, a release protection layer 328 such as AlOx can be deposited in block 244 using atomic layer deposition (ALD), physical vapor deposition (PVD), or other appropriate techniques and patterned in block 248 to protect sidewalls 329 of the electrodes in the first and second metal layers 316 and 324 and the sandwiched piezoelectric layer 320, as shown in FIG. 3F. Blocks 244 and 248 of FIG. 2 can be omitted in some implementations. In one implementation, the release protection layer 328 is patterned in block 248 to overlay second metal layer 324, as shown in FIG. 3F. Side areas 319 remain exposed. Release protection layer 328 can be formed of SiON, and have a thickness of about 5000 Angstroms. Release protection layer 328 is then removed after release of SAC layer 308.

In block 252, SAC layer 308 is then removed to define an air cavity 332, as shown in FIGS. 3G and 4F. In one implementation, SAC layer 308 is released by exposing the structure to XeF₂ gas or SF₆ plasma, for instance, when the SAC layer 308 is formed of Mo or a-Si. HF can be used when SAC layer 308 is formed of SiON or SiOx. FIG. 4G shows a perspective back view of the resulting resonator structure, with substrate 304 not shown to better illustrate cavity 332. The cavity 332 region is essentially defined by the absence of SAC layer 308; thus, cavity 332 includes side areas 319 and a portion underlying the first metal strip 318 of the resonator.

Following block 252, a metal interconnect layer can be deposited and patterned outside of the resonator structure to define transmission lines to the first and second metal layers 316 and 324. AlSi, AlCu, plated Cu, or other appropriate material can be used to form the metal interconnect layer.

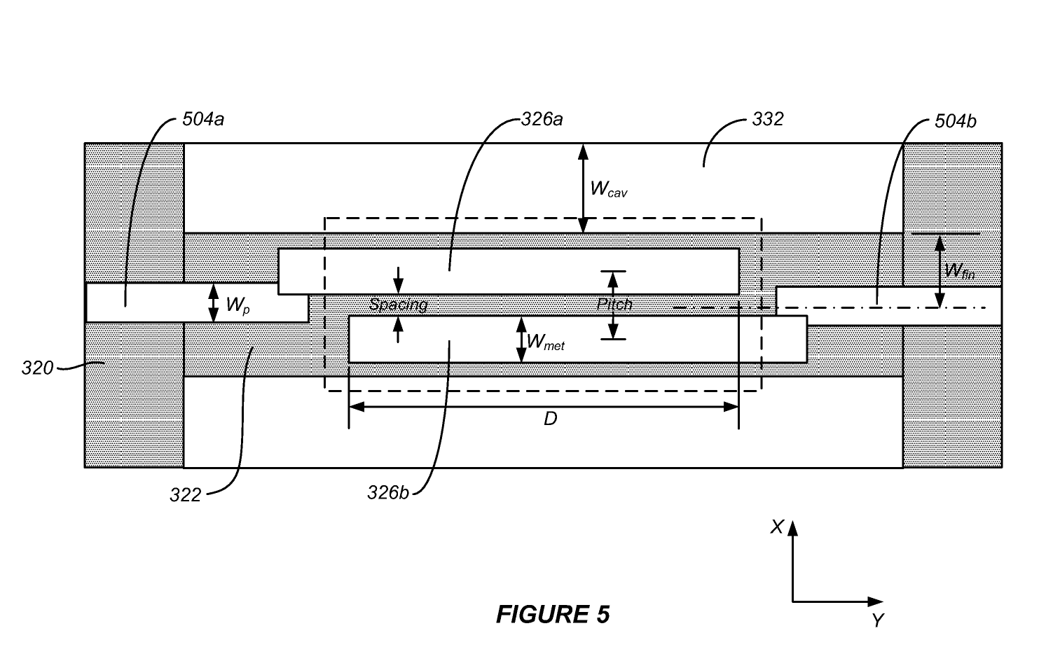

FIG. 5 shows an example of a top view of a staggered resonator device in accordance with one implementation. In the implementation of FIG. 5, the resonator structure is configured as a CMR, with the electrodes in the respective conductive layers having longitudinal axes substantially parallel to one another and extending along the Y axis, as illustrated. A resonator structure generally has a finger width, Wfin, representing the width of each sub-resonator, which primarily includes one electrode and half of the width of the exposed piezoelectric material on either side of the one electrode along the X axis, for example, as shown in FIG. 5. The electrode width, that is, the width of an individual electrode, Wmet, is generally smaller than the finger width, to limit the feed-through capacitance between electrodes. The pitch of the resonator structure generally refers to the distance between mid-points of electrodes along the X axis, as shown in FIG. 5. The spacing of electrodes refers to the gap between the edges of adjacent electrodes along the X axis, as shown in FIG. 5. The resonant frequency of the resonator structures disclosed herein is primarily determined by the finger width or pitch. The electrode width and spacing have second-order effects on the frequency. The finger width and pitch are correlated with the electrode width and spacing parameters, by definition. Pitch is often equal to finger width, as shown in FIG. 5.

In FIG. 5, in one example, the upper electrodes 326a and 326b have an electrode width along the X axis, Wmet, of 4.8 um. Connecting members 504a and 504b, which can include tethers in one example, are coupled to the respective electrodes 326a and 326b. The connecting members 504a and 504b have a connecting member width, Wp, which can be smaller than Wmet in this example. In other instances, Wp is the same size or larger than Wmet, depending on the desired configuration. The finger width of the electrodes, Wfin, which corresponds to the half-width of the piezoelectric layer 322 in this example, is 6.4 um. Wcav, the width of the cavity along the X axis can be an integer multiple of Wfin, such as 2*Wfin (e.g., 12.8 um) or other measurement. Thus, in this instance, Wcav is approximately the same as the full piezoelectric layer width. In this example, a distance D, in which the upper electrodes 326a and 326b are adjacent to one another, can be on the order of 128 um or 256 um, by way of example.

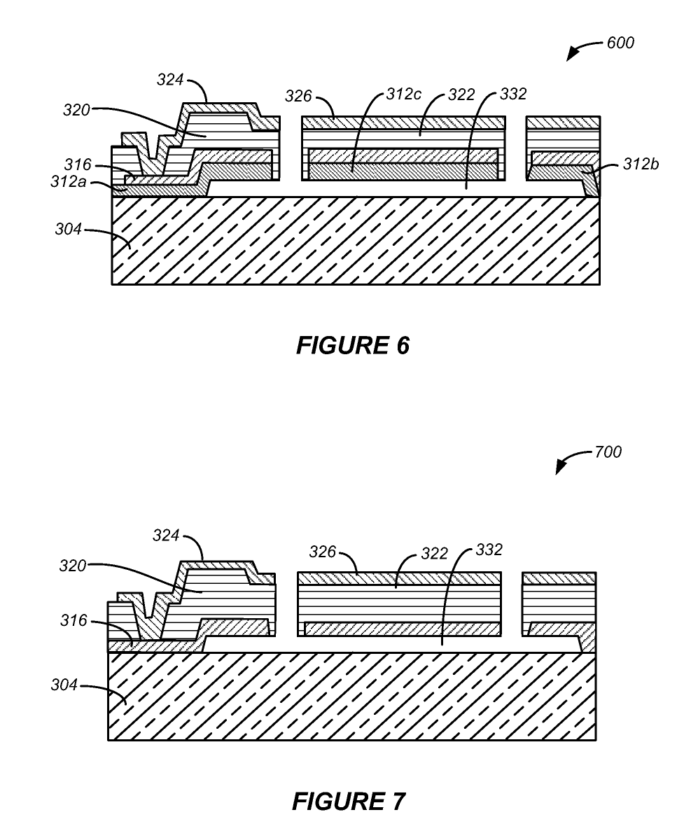

FIG. 6 shows an example of a cross-sectional schematic illustration of a temperature-compensated resonator structure in accordance with one implementation. The temperature compensated structure 600 of FIG. 6 can be fabricated using the same processes as described above with respect to FIGS. 2-4, with a slight variation. Here, the post oxide layer 312 is patterned in block 216 such that a strip of the post oxide layer 312c remains and underlies the lower electrode(s) 318. In one implementation, the post oxide strip 312c is aligned with the overlaying lower electrode 318, piezoelectric layer 322, and upper electrodes 326 of the resonator structure. This strip 312c defines a temperature compensation layer for the resonator structure. The thickness of post oxide layer as a temperature compensation layer is often dependent on the choice of materials for the piezoelectric and electrode layers. In one case where the piezoelectric material is AlN, the electrodes are AlCu, Mo or a combination of both, and the post oxide layer is SiO2, the thickness for the SiO2 layer is of comparable magnitude to the thickness of the AlN layer.

In FIG. 6, the temperature compensation layer 312c provides resonators with a lower magnitude temperature-coefficient of frequency (TCF). This can be achieved by the selection of an appropriate material and layer thicknesses, as described above, for post oxide layer 312, which serves as the thin-film compensation layer.

FIG. 7 shows an example of a cross-sectional schematic illustration of an airgap resonator structure in accordance with one implementation. The airgap structure 700 of FIG. 7 can also be fabricated using essentially the same processes as described above with respect to FIGS. 2-4. Here, blocks 212 and 216 have been omitted, so that no post oxide layer is formed. The lower electrode layer is thus deposited and patterned in blocks 220 and 224 so that it directly overlays SAC layer 308 and the exposed areas 310 of substrate 304. The remaining fabrication blocks can be performed as described above with respect to FIGS. 2-4.

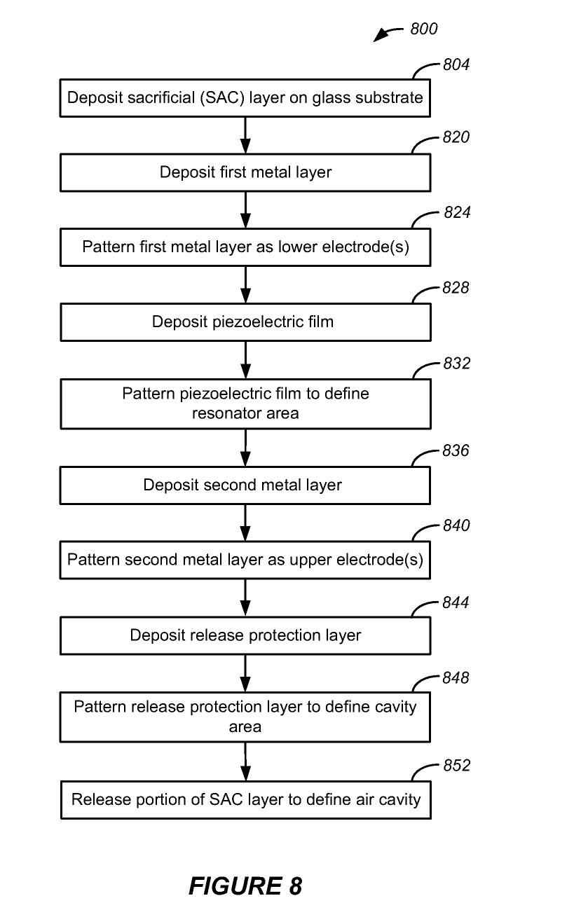

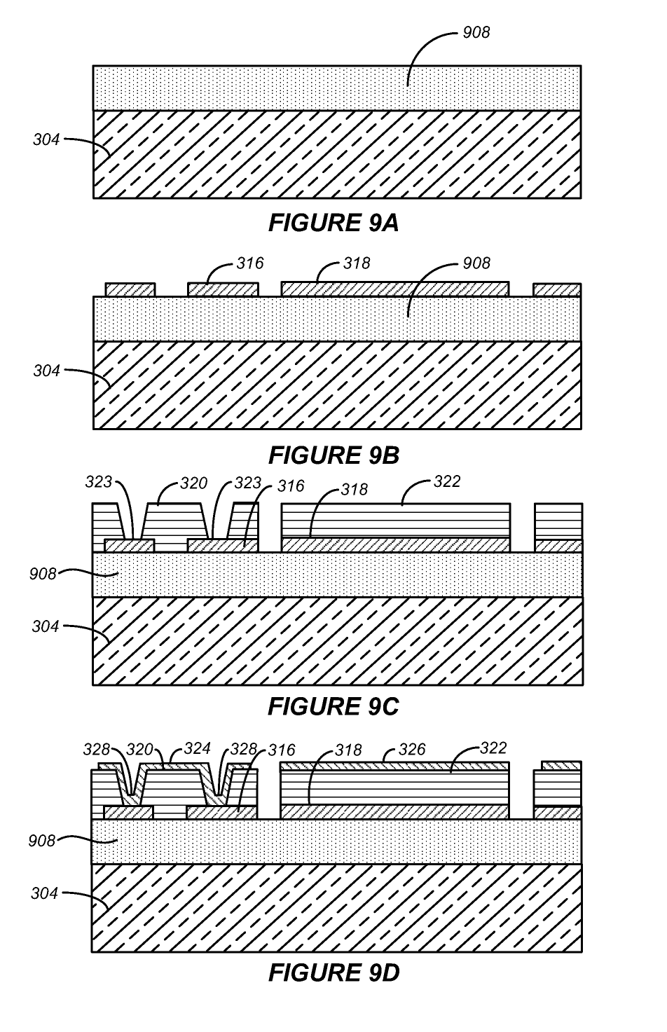

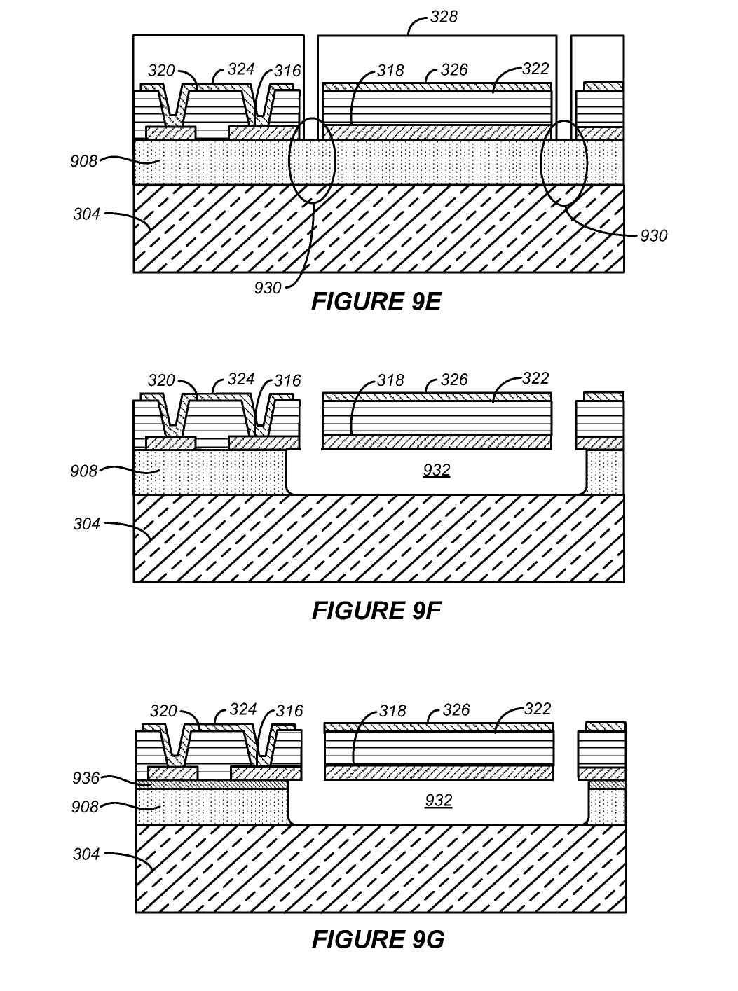

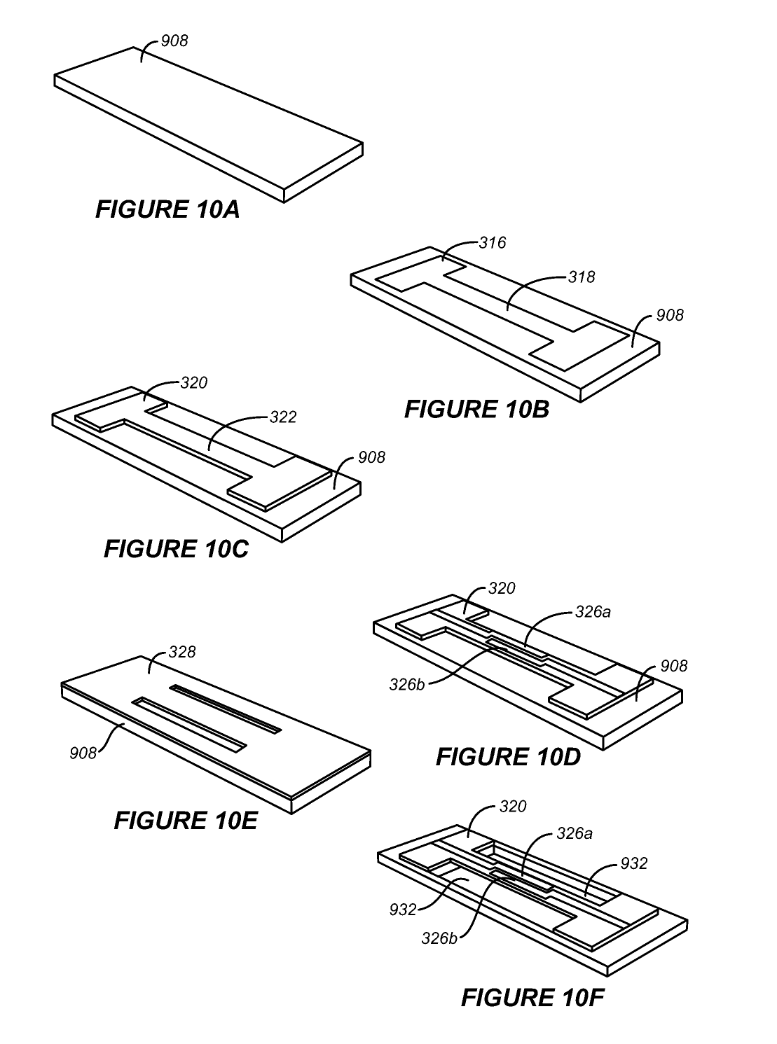

FIG. 8 shows an example of a flow diagram illustrating a process for forming a co-planar resonator structure, performed in accordance with one implementation. FIGS. 9A-9G show examples of cross-sectional schematic illustrations of stages of co-planar resonator fabrication in accordance with a process, for instance, as represented in FIG. 8. FIGS. 10A-10F show examples of perspective views of stages of co-planar resonator fabrication in accordance with a process, for instance, as represented in FIG. 8.

In FIG. 8, the device structures of FIGS. 9 and 10 can be fabricated using fewer masks than the process of FIG. 2 to form the staggered structures of FIGS. 3 and 4. In FIG. 8, in some implementations, materials used to form the respective layers and dimensions, e.g., thicknesses of the respective layers can be the same or similar as those described above with respect to the staggered structure of FIGS. 3 and 4. Examples of variations in such materials and dimensions are discussed below.

In FIG. 8, process 800 begins in block 804 in which a SAC layer 908 is deposited on glass substrate 304. Unlike process 200, in some implementations, there is no corresponding patterning associated with the deposition of SAC layer 908. The masks described above in conjunction with blocks 208 and 216 (to pattern the SAC layer and post oxide anchors) are not used in association with block 804, in some examples. SAC layer 908 covers the substrate region 304, as shown in FIG. 10A. In some implementations, SAC layer 908 is desirably an insulating material and formed of SiON or SiOx, rather than Mo or a-Si or poly-crystalline silicon. In some implementations, when SiON or SiOx are used, a suitable thickness of SAC layer 308 is in the range of about 0.5 um to 3 um. In other examples, SAC layer 908 is in the range of about 3 um to 5 um. In alternative implementations, SAC layer 908 has the same, a larger, or a smaller thickness than SAC layer 308.

In blocks 820 and 824, a first metal layer 316 is deposited and patterned to define lower electrode(s) 318, as described above in blocks 220 and 224, and as shown in FIGS. 9B and 10B. Here, because the post oxide anchors have not been formed before depositing and forming the lower electrode(s), the first metal layer 316 including lower electrode(s) 318 is substantially oriented in parallel planes with SAC layer 908 and the underlying glass substrate 304.

In blocks 828 and 832, a piezoelectric film 320 is deposited and patterned to define strip 322 to be sandwiched between the upper and lower metal layers of electrodes, as described above in blocks 228 and 232. This is shown in FIGS. 9C and 10C.

In blocks 836 and 840, a second metal layer 324 is deposited and patterned to define upper electrodes 326, as described above in blocks 236 and 240. The corresponding structures are illustrated in FIGS. 9D and 10D. Again, because the post oxide anchors are not fabricated in the co-planar structures of FIGS. 9 and 10, the upper electrodes, piezoelectric layer, and lower electrodes are all substantially oriented in parallel planes with sacrificial layer 908 and glass substrate 304.

In block 844, a release protection layer 328 is optionally deposited, as described above in block 244. In block 848, release protection layer 328 is patterned to expose portions of SAC layer 908, and in conjunction with the underlying layers defines border regions 930 of a desired cavity to be formed in SAC layer 908, as shown in FIGS. 9E and 10E. In block 852, a portion of SAC layer 908 within the border regions 930 is released to define a cavity area 932, as shown in FIGS. 9F and 10F. The release etch is timed so as to completely release the active part of the resonator from the underlying substrate.

In an alternative implementation, an insulator layer is deposited between SAC layer 908 and the first metal layer 316, as shown in FIG. 9G. In this implementation, the insulating layer 936 can be deposited on the SAC layer 908 following block 804 and before depositing first metal layer 316 in block 820. Such a layer 908 increases the electrical isolation of the lower electrodes in layer 316.

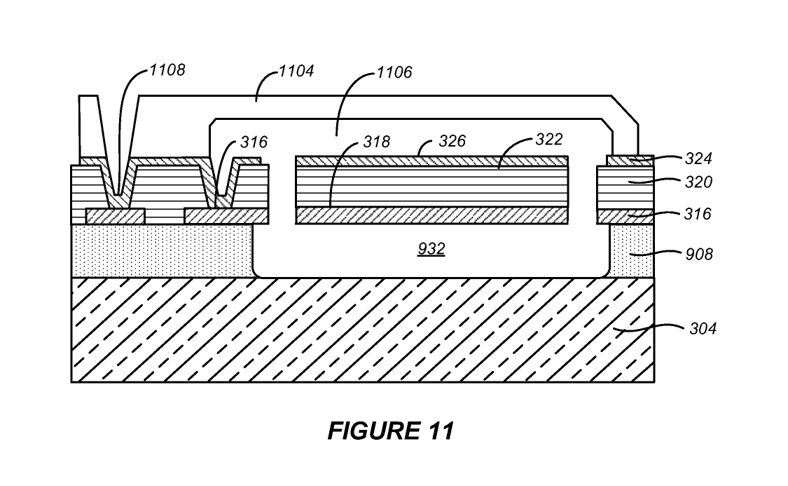

FIG. 11 shows an example of a cross-sectional schematic illustration of an alternative implementation of a co-planar resonator structure with thin-film encapsulation. Here, a post oxide or planarization layer 1104 has been formed over the second metal layer 324, separated by a gap 1106. The encapsulation layer overlays at least a portion of the upper electrode layer. The planarization layer can have a thickness of about 1 um, by way of example. The planarization layer 1104 acts as a shell or sealant to protect the underlying structure. The gap 1106 separating planarization layer 1104 from the second metal layer 324 can be formed by depositing and removing a further SAC layer, using techniques as described above to form the cavity region of the resonator structure. That is, the further SAC layer would be deposited on the upper metal layer 324 and patterned, followed by deposition and patterning of the planarization layer 1104, and then release of the further SAC layer. A via 1108 can be formed to provide contacts to metal regions 328 and 323 of the respective metal layers.

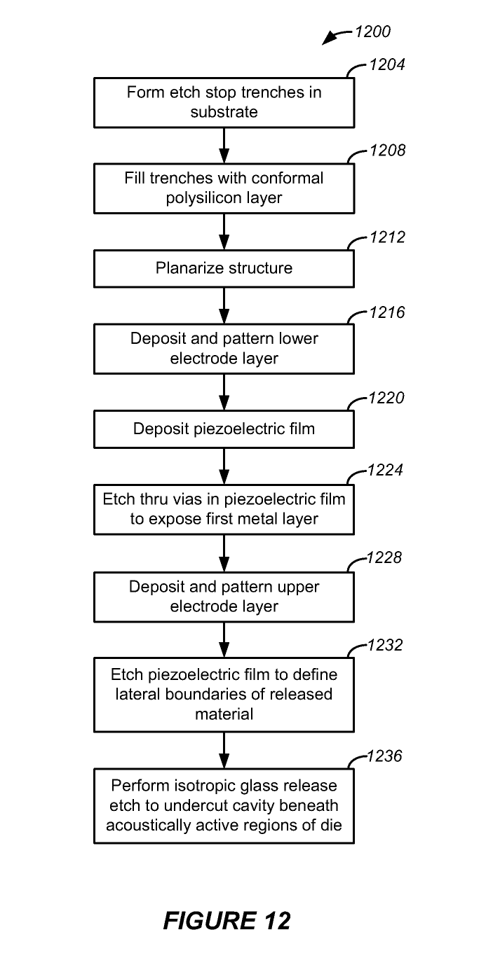

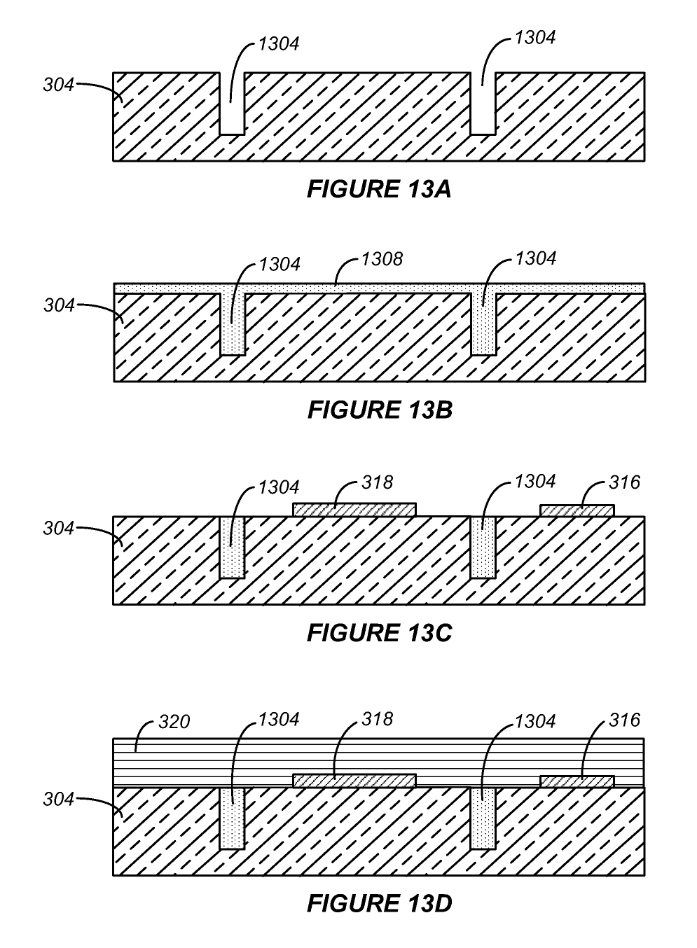

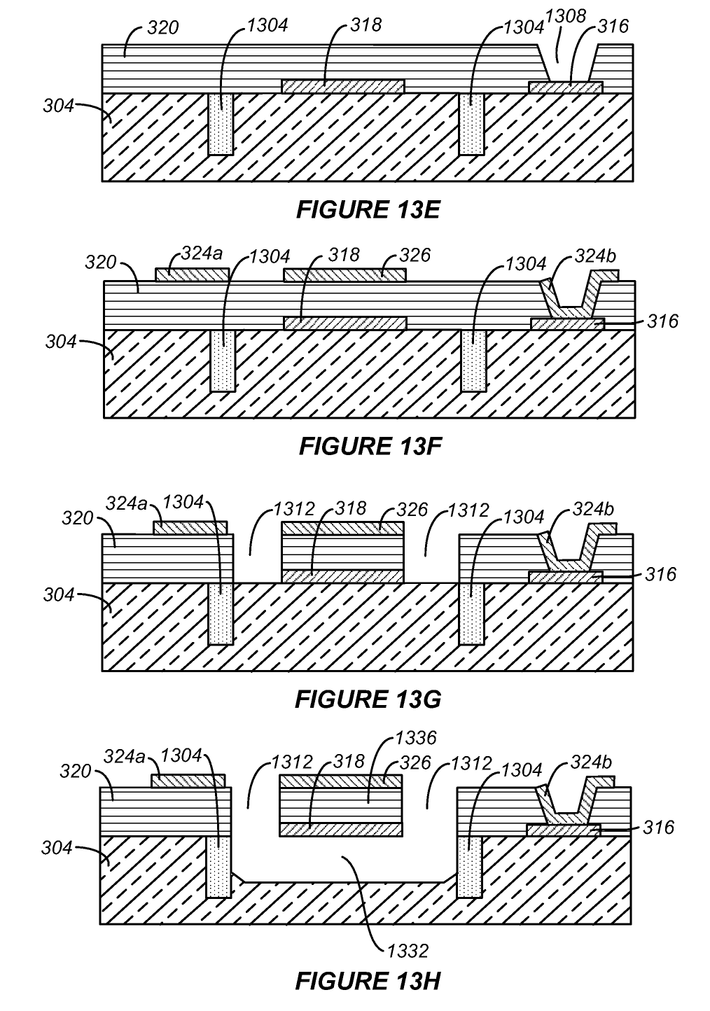

FIG. 12 shows an example of a flow diagram illustrating a process 1200 for forming a resonator structure using refilled etch stop trenches, performed in accordance with one implementation. FIGS. 13A-13H show examples of cross-sectional schematic illustrations of stages of resonator fabrication in accordance with a process, for instance, as represented in FIG. 12.

In FIG. 12, process 1200 begins in block 1204 in which etch stop trenches 1304 are formed in substrate 304, as shown in FIG. 13A. For example, trenches 1304 can be formed by anisotropic etching. In block 1208, as shown in FIG. 13B, the trenches 1304 are filled with a conformal polysilicon (poly-Si) layer 1308. The poly-Si layer is deposited over substrate 304, for instance, using low-pressure chemical vapor deposition (LPCVD), plasma-enhanced chemical vapor deposition (PECVD), electron cyclotron resonance (ECR) deposition, or other appropriate deposition techniques. The structure is planarized in block 1212 to remove a surface portion of polysilicon layer 1308, as shown in FIG. 13C, leaving the trenches 1304 filled with poly-Si. In block 1216, a first metal layer 316 with lower electrode(s) 318 is deposited and patterned, as described above in blocks 220 and 224. In block 1220, a piezoelectric film 320 is deposited as described above in block 228, and as shown in FIG. 13D. In block 1224, as shown in FIG. 13E, thru vias 1308 are etched in piezoelectric film 320 to expose a portion of first metal layer 316. In block 1228, as shown in FIG. 13F, upper electrode(s) 326 are formed from second metal layer 324, as described above, with one portion of second metal layer 324b in contact with first metal layer 316.

As shown in FIG. 13G, process 1200 continues in block 1232, in which piezoelectric film 320 is etched to define lateral boundaries 1312 of material to be released, as further described below. For example, anisotropic etching techniques can be used in block 1232. Following block 1232, in block 1236, an isotropic glass release etch is performed to define a cavity 1332 beneath acoustically active resonator structure 1336 of the die, as shown in FIG. 13H. For example, an HF vapor etch or CF₄ etch can be performed in block 1236. The interior surfaces of poly-Si filled trenches 1304 limit the lateral extent of the glass release etch of block 1236 and define boundaries of the cavity 1332.

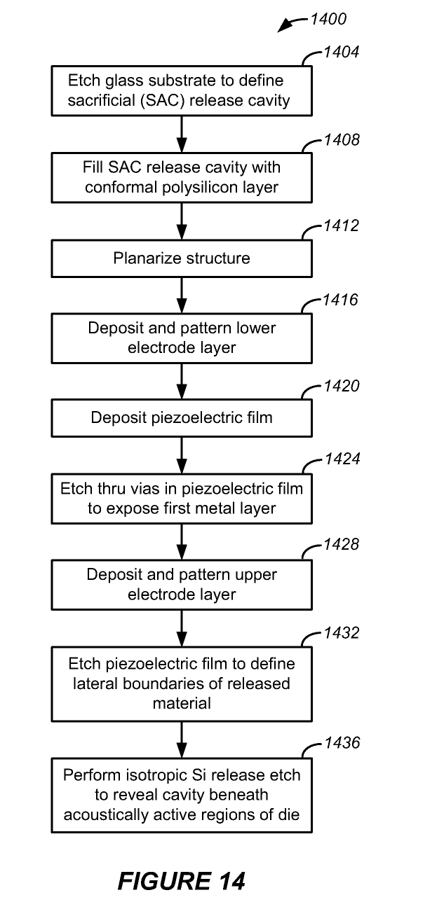

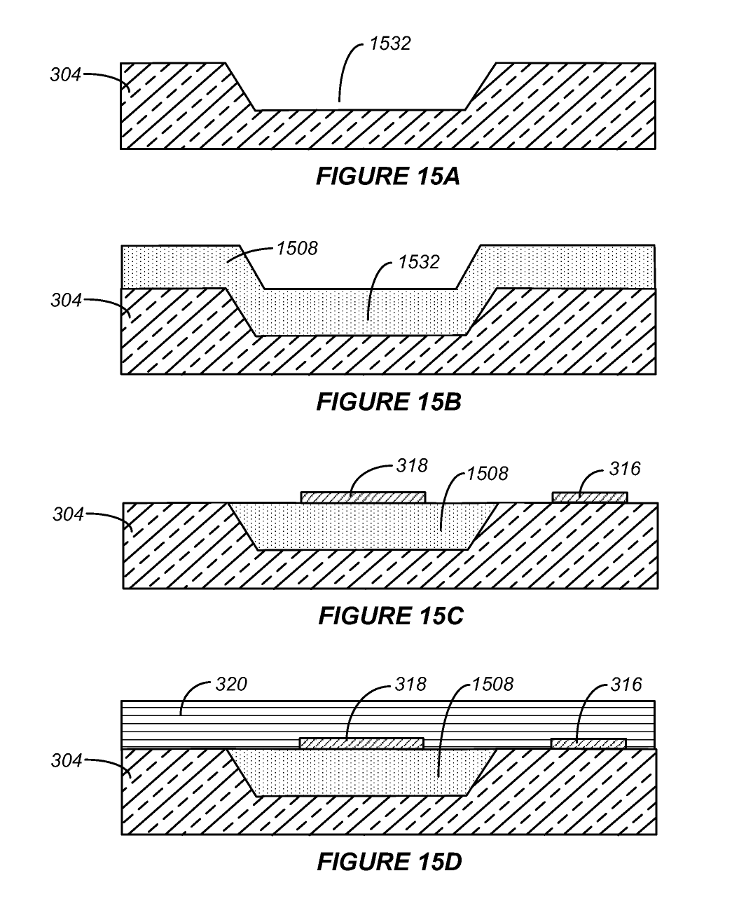

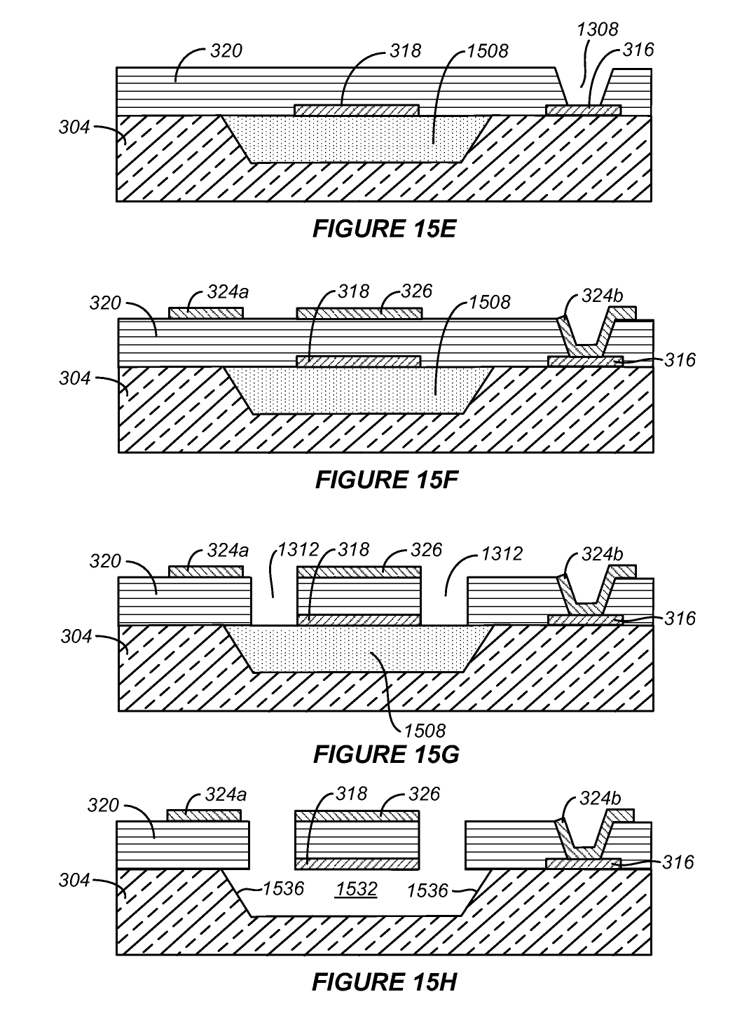

FIG. 14 shows an example of a flow diagram illustrating a process 1400 for forming a resonator structure using a refilled sacrificial (SAC) release cavity, performed in accordance with one implementation. FIGS. 15A-15H show examples of cross-sectional schematic illustrations of stages of resonator fabrication in accordance with a process, for instance, as represented in FIG. 14.

Process 1400 begins in block 1404, in which the substrate 304 is etched to define a sacrificial (SAC) release cavity 1532, as shown in FIG. 15A. In block 1408, a conformal poly-Si layer 1508 is deposited, filling cavity 1532, as shown in FIG. 15B. Blocks 1412-1432 are essentially the same as blocks 1212-1232 of FIG. 12 described above, with the depositing of layers and etching illustrated in FIGS. 15C-15G similar to that illustrated in FIGS. 13C-13G. In block 1436, an isotropic Si release etch is performed to remove the poly-Si beneath acoustically active resonator structure 1336 of the die, as shown in FIG. 15H, to reveal cavity 1532. For example, a XeF₂ gas release or SF₆ plasma release can be performed. The angled walls 1536 of the substrate 304 limit the lateral extent of the isotropic Si release etch of block 1436 and define border regions of the cavity 1532.

The piezoelectric materials that can be used in fabrication of the piezoelectric layers of electromechanical systems resonators disclosed herein include, for example, aluminum nitride, zinc oxide, gallium arsenide, aluminum gallium arsenide, gallium nitride, quartz and other piezoelectric materials such as zinc-sulfide, cadmium-sulfide, lithium tantalate, lithium niobate, lead zirconate titanate, members of the lead lanthanum zirconate titanate family, doped aluminum nitride (AlN: Sc), and combinations thereof. The conductive layers of upper and lower electrodes may be made of various conductive materials including platinum, aluminum, molybdenum, tungsten, titanium, niobium, ruthenium, chromium, doped polycrystalline silicon, doped AlGaAs compounds, gold, copper, silver, tantalum, cobalt, nickel, palladium, silicon germanium, doped conductive zinc oxide, and combinations thereof. In various implementations, the upper metal electrodes and/or the lower metal electrodes can include the same conductive material(s) or different conductive materials.

The structures, devices, apparatus, and systems described above with respect to FIGS. 1-15 may be implemented in any electronic device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry).

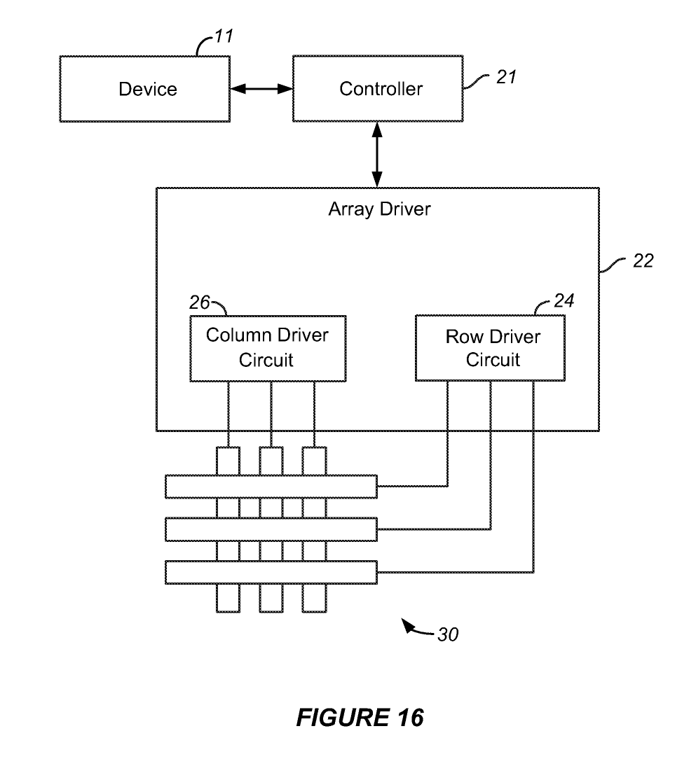

FIG. 16 shows an example of a system block diagram illustrating an electronic device incorporating a 3×3 interferometric modulator (IMOD) display. The electronic device of FIG. 16 represents one implementation in which a resonator device 11 constructed in accordance with the implementations described above with respect to FIGS. 1-15 can be incorporated. The electronic device in which device 11 is incorporated may, for example, form part or all of any of the variety of electrical devices and electromechanical systems devices set forth above, including both display and non-display applications.

Here, the electronic device includes a controller 21, which may include one or more general purpose single- or multi-chip microprocessors such as an ARM®, Pentium®, 8051, MIPS®, Power PC®, or ALPHA®, or special purpose microprocessors such as a digital signal processor, microcontroller, or a programmable gate array. Controller 21 may be configured to execute one or more software modules. In addition to executing an operating system, the controller 21 may be configured to execute one or more software applications, including a web browser, a telephone application, an email program, or any other software application.

The controller 21 is configured to communicate with device 11. The controller 21 can also be configured to communicate with an array driver 22. The array driver 22 can include a row driver circuit 24 and a column driver circuit 26 that provide signals to, e.g., a display array or panel 30. Although FIG. 16 illustrates a 3×3 array of IMODs for the sake of clarity, the display array 30 may contain a very large number of IMODs, and may have a different number of IMODs in rows than in columns, and vice versa. Controller 21 and array driver 22 may sometimes be referred to herein as being “logic devices” and/or part of a “logic system.”

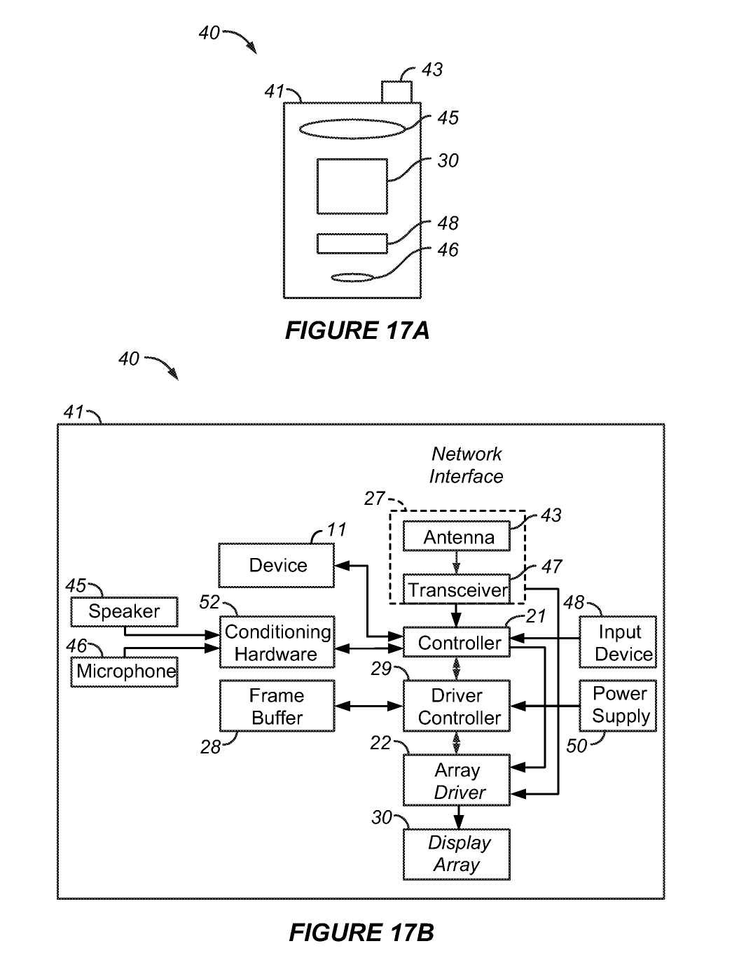

FIGS. 17A and 17B show examples of system block diagrams illustrating a display device 40 that includes a plurality of interferometric modulators. Display device 40 represents one example of an electronic device as described above. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 17B. The display device 40 includes a housing 41 and can include additional components at least partially enclosed therein. For example, the display device 40 includes a network interface 27 that includes an antenna 43, which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43. One or more of the resonator structures described above can be incorporated in transceiver 47.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level. Controller 21 is also configured to interact with device 11 to perform desired operations.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components. In one implementation, device 11 is incorporated as a component of conditioning hardware 52.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A process for forming a resonator structure comprising:
depositing a sacrificial layer on an insulating substrate;
forming a lower electrode layer proximate the sacrificial layer;
depositing a piezoelectric layer on the lower electrode layer;
forming an upper electrode layer on the piezoelectric layer; and
removing at least a portion of the sacrificial layer to define a cavity such that at least a portion of the lower electrode layer is spaced apart from the insulating substrate.

2. The process of claim 1, further comprising:
before forming the lower electrode layer, depositing a post oxide layer at least partially overlaying the sacrificial layer, the lower electrode layer at least partially overlaying the post oxide layer.

3. The process of claim 2, further comprising:
patterning the post oxide layer to define post oxide anchors and expose a portion of the sacrificial layer.

4. The process of claim 1, further comprising:
before removing the at least a portion of the sacrificial layer, depositing a release protection layer on the upper electrode layer.

5. The process of claim 1, a portion of the upper electrode layer, a portion of the piezoelectric layer, and a portion of the lower electrode layer being patterned to expose one or more areas of the sacrificial layer.

6. The process of claim 1, removing the at least a portion of the sacrificial layer including performing an isotropic release etch process.

7. The process of claim 6, performing the isotropic release etch process including introducing a XeF₂ gas or SF₆ plasma.

8. The process of claim 1, further comprising:
forming an encapsulation layer overlaying at least a portion of the upper electrode layer.

9. The process of claim 8, a portion of the encapsulation layer being spaced apart from the upper electrode layer.

10. The process of claim 1, further comprising:
removing a portion of the insulating substrate to define a sacrificial release region, at least a portion of the deposited sacrificial layer situated in the sacrificial release region.

11. The process of claim 10, the sacrificial release layer including conformal polysilicon.

12. The process of claim 10, the removed portion of the sacrificial layer being the at least a portion of the deposited sacrificial layer situated in the sacrificial release region.

13. The process of claim 10, removing the portion of the insulating substrate including performing an isotropic glass release etch process.

14. A process for forming a resonator structure comprising:
removing portions of an insulating substrate to define trenches in the substrate;
depositing a material in the trenches to define border regions;
forming a lower electrode layer proximate the sacrificial layer;
depositing a piezoelectric layer on the lower electrode layer;
forming an upper electrode layer on the piezoelectric layer; and
removing at least a portion of the insulating substrate between the border regions to define a cavity such that at least a portion of the lower electrode layer is spaced apart from the insulating substrate.

15. The process of claim 14, the material in the trenches including conformal polysilicon.

16. The process of claim 14, removing the at least a portion of the insulating substrate between the border regions including performing an isotropic glass release etch process.

17. A resonator device comprising:
an insulating substrate;
a lower electrode layer having at least a portion spaced apart from the substrate by a cavity defined by release of at least a portion of a sacrificial layer deposited on the insulating substrate;
a piezoelectric layer disposed on the lower electrode layer opposite the insulating substrate; and
an upper electrode layer disposed on the piezoelectric layer opposite the lower electrode layer.

18. The device of claim 17, the insulating substrate including glass.

19. The device of claim 17, the insulating substrate including a ceramic material.

20. The device of claim 17, the sacrificial layer including a material selected from the group consisting of: molybdenum, germanium, amorphous silicon, and poly-crystalline silicon.

21. The device of claim 17, the sacrificial layer including a material selected from the group consisting of: silicon oxynitride and silicon oxide.

22. The device of claim 17, further comprising:
a compensation layer disposed between the lower electrode layer and the cavity.

23. The device of claim 17, further comprising:
a post oxide layer having a portion disposed between a portion of the lower electrode layer and the substrate.

24. The device of claim 17, further comprising:
a sacrificial layer portion disposed between a portion of the lower electrode layer and the substrate.

25. The device of claim 17, further comprising:
an encapsulation layer overlaying at least a portion of the upper electrode layer.

26. The device of claim 25, a portion of the encapsulation layer being spaced apart from the upper electrode layer.

27. The device of claim 17, further comprising:
a display;
a processor configured to communicate with the display, the processor being configured to process image data; and
a memory device configured to communicate with the processor.

28. The device of claim 27, further comprising:
a driver circuit configured to send at least one signal to the display.

29. The device of claim 28, further comprising:
a controller configured to send at least a portion of the image data to the driver circuit.

30. A resonator device comprising:
an insulating substrate;
a lower electrode layer overlaying the insulating substrate, the lower electrode layer having a portion spaced apart from the substrate by a cavity defined by removal of a sacrificial layer;
a piezoelectric layer overlaying the lower electrode layer opposite the substrate; and
an upper electrode layer overlaying the piezoelectric layer opposite the lower electrode layer.

31. A resonator device comprising:
an insulating substrate;
a sacrificial layer overlaying the substrate;
a lower electrode layer overlaying the sacrificial layer opposite the substrate, the lower electrode layer having a region spaced apart from the substrate by a cavity defined in the sacrificial layer by release of a portion of the sacrificial layer;
a piezoelectric layer overlaying the lower electrode layer opposite the sacrificial layer; and
an upper electrode layer overlaying the piezoelectric layer opposite the lower electrode layer.
